(19) United States
(12) Patent Application Publication
(10) Pub. No.: US 2016/0013759 A1
(43) Pub. Date: Jan. 14, 2016

(54) AMPLIFIER CIRCUITRY FOR ENVELOPE MODULATORS, ENVELOPE MODULATORS INCORPORATING SAID AMPLIFIER CIRCUITRY AND METHOD OF MODULATING A SIGNAL ENVELOPE

(71) Applicant: KABUSHIKI KAISHA TOSHIBA, Minato-ku, Tokyo (JP)

(72) Inventor: Gavin WATKINS, Bristol (GB)

(21) Appl. No.: 14/773,230

(22) PCT Filed: Mar. 7, 2013
(86) PCT No.: PCT/GB2013/050566

§ 371 Date: Sep. 4, 2015

(51) Int. Cl. H03F 1/02; H03F 3/21; H03F 3/19; H03F 1/52; H03F 3/387

(52) U.S. Cl. CPC H03F 1/0222; H03F 1/52; H03F 3/387; H03F 3/19; H03F 3/211; H03F 2200/444; H03F 2200/451

(57) ABSTRACT

Amplifier circuitry for an envelope modulator comprising: a plurality of amplifiers for driving a load, each amplifier receiving an input representing an envelope of a signal to be amplified, and one or more charge storage devices coupled to one or more of said plurality of amplifiers. The plurality of amplifiers and charge storage device(s) receive a supply voltage V+ and the charge storage device(s) are charged to the supply voltage V+ initially. The plurality of amplifiers are arranged so that the output of a second one of said plurality of amplifiers is connected to one of the charge storage devices, which is in turn connected to a first one of said amplifiers for supplying a charge to the first amplifier. By this configuration, an increase in the output voltage of the second amplifier causes the charge supplied to the first amplifier to increase above the supply voltage V+ such that the output voltage of the load driven by the amplifier circuitry is increased above the supply voltage V+.

### FIELD

Embodiments described herein relate generally to amplifier circuitry and power efficient envelope modulators. Embodiments described herein specifically relate to amplifier circuitry having a plurality of amplifiers cascaded with power supplies, where the output of one amplifier drives the power supply of the next for providing an amplified output. Embodiments also relate to envelope modulators incorporating such amplifier circuits and methods for amplifying a signal.

### BACKGROUND

Envelope modulators often use a linear class AB or a class B amplifier to amplify high frequency AC signal components. Envelope modulators that use such an amplifier to amplify the entire bandwidth of a signal are inherently inefficient. Another type of envelope modulator splits the frequencies of the signals to be operated upon and applies only a higher signal frequency component to a linear amplifier, thereby increasing the efficiency to some degree. However, this configuration has two draw backs. Firstly the frequency response of the modulator is distorted by a null being present in the amplitude response and a phase flip in the phase response. These effects degrade the signal fidelity which contributes to the error vector magnitude (EVM) and adjacent channel power ratio (ACPR). Secondly, a large inductor is required in the combining network which takes up considerable board space making this architecture unsuitable for integrated circuit integration and expensive.

### BRIEF DESCRIPTION OF THE DRAWINGS

Embodiments of the present invention will now be described by way of example only and with reference to the accompanying drawings, in which:

FIG. 1 shows a split frequency envelope modulator that currently exists;

FIG. 2 shows a DC coupled envelope modulator using class G techniques that currently exists;

FIG. 3 shows a known charge pump voltage doubler;

FIG. 4 shows amplifier circuitry according to an embodiment in which three amplifiers are shown, as one example;

FIG. 5 depicts operating states of the amplifier circuitry of FIG. 4;

FIG. 6 shows an envelope modulator incorporating the amplifier circuitry of FIG. 4;

FIG. 7 shows an a split frequency envelope modulator incorporating the amplifier circuitry of FIG. 4; and

FIGS. 8 and 9 show implementations of biasing networks to achieve the operation states shown in FIG. 5.

### DETAILED DESCRIPTION

The embodiments provide an amplifier circuitry in which a plurality of amplifiers are cascaded with power supplies to reproduce high PAPR signals efficiently for envelope modulation applications.

According to one embodiment, there is provided amplifier circuitry for an envelope modulator comprising:

a plurality of amplifiers for driving a load, each amplifier receiving an input representing an envelope of a signal to be amplified; one or more charge storage devices coupled to one or more of said plurality of amplifiers, said plurality of amplifiers and charge storage device(s) arranged to receive a supply voltage V+, the charge storage devices being charged to said supply voltage V+; wherein the plurality of amplifiers are arranged so that the output of a second one of said plurality of amplifiers is connected to one of the charge storage devices, said charge storage device being connected to a first one of said amplifiers for supplying a charge to the first amplifier, whereby an increase in the output voltage of the second amplifier causes the charge supplied to the first amplifier to increase above the supply voltage V+ such that the output voltage of the load driven by the amplifier circuitry is increased above the supply voltage V+.

According to another embodiment, there is provided an envelope modulator comprising the amplifier circuitry set out above, the envelope modulator further including:

an RF input for receiving an RF signal that is to be amplified;

an envelope detector for providing an envelope input signal indicative of an instantaneous magnitude of the envelope of said RF signal to said amplifier circuitry; and

an RF power amplifier for providing an amplified RF output signal;

wherein the amplifier circuitry is configured to feed an amplified envelope signal output to a voltage supply input of the RF power amplifier.

According to another embodiment, there is provided an envelope modulator comprising the amplifier circuitry set out above, the envelope modulator being a split- frequency envelope modulator further including:

an RF input for receiving an RF signal that is to be amplified;

an envelope detector for providing an envelope signal indicative of an instantaneous magnitude of the envelope of said RF signal;

a splitting network for receiving the envelope signal from the envelope detector and splitting said envelope signal into a high frequency component and a low frequency component, the splitting network being arranged to provide the high frequency component of the envelope signal to the amplifier circuitry, and to provide the low frequency component of the envelope signal to a further amplifier;

a combining network for combining the outputs of the amplifier circuitry and further amplifier provide an amplified envelope signal; and

an RF power amplifier for providing an amplified RF output signal,

wherein, the amplifier circuitry is configured to feed an amplified envelope signal output to a voltage supply input of the RF power amplifier.

According to another embodiment, there is provided a method for amplifying a signal using the amplifier circuitry set out above comprising the steps of:

providing an input signal representing an envelope of a signal to be amplified to a plurality of amplifiers, said plurality of amplifiers provided for driving a load;

providing one or more charge storage devices coupled to one or more of said plurality of amplifiers;

providing a supply voltage V+ to said plurality of amplifiers and charge storage devices, the charge storage devices being charged to said supply voltage V+; and connecting the output of a second one of said plurality of to one of the charge storage devices, said charge storage device being connected to a first one of said amplifiers for supplying a charge to the first amplifier, whereby an increase in the output voltage of the second amplifier causes the charge supplied to the first amplifier to increase above the supply voltage V+ such that the output voltage of the load driven by the amplifier circuitry is increased above the supply voltage V+.

According to another embodiment there is provided a RF amplifier comprising an envelope modulator as described above.

According to another embodiment there is provided a base station or a transmitter comprising such a RF amplifier.

According to another embodiment there is provided a method for envelope modulation using any one of the envelope modulators of the described embodiments set out above.

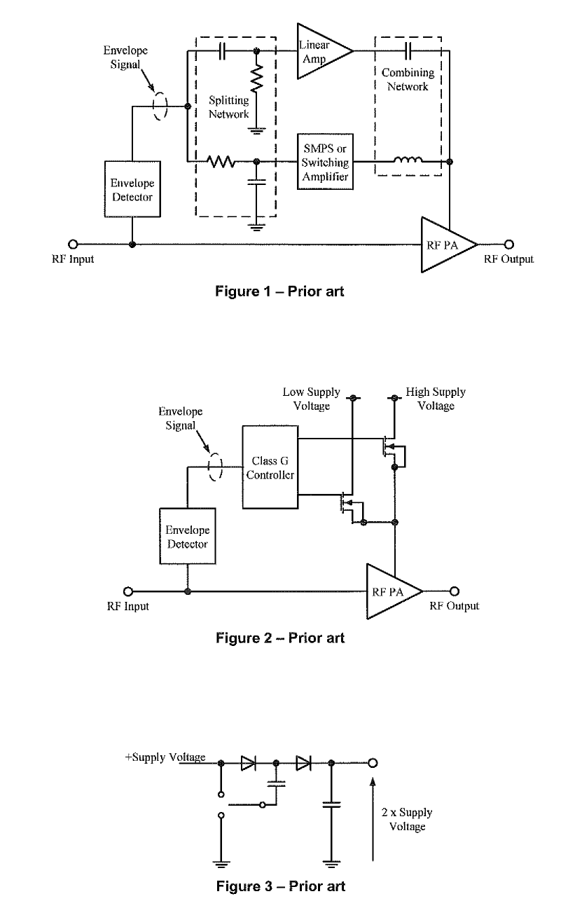

Known envelope modulators are generally based on a split—frequency architecture such as shown in FIG. 1 comprising a frequency separator arranged to separate a high frequency AC component of an envelope signal to be modulated and a low frequency DC component of the envelope signal, and to provide the high frequency component to a first output and the low frequency component to a second output. The frequency separator comprises a high pass filter and a low pass filter provided in parallel with a common input. A linear amplifier is used in the high frequency path AC such as shown in FIG. 1 to amplify the signal passed by the high pass filter and a capacitor is used to feed this to an RF amplifier. The low frequency signal path uses a switched mode power supply (SMPS) to amplify the low frequency components of the envelope signal and this is fed to the RF amplifier via an inductor. The inductor and capacitor forms a combining network in the envelope modulator of FIG. 1.

Though the efficiency of this configuration may be improved by using a class G or class H amplifier in the high frequency path, split frequency envelope modulators such as shown in FIG. 1 are hindered by the fact that the high frequency AC and the low frequency DC components of the envelope signal are provided by two separate amplifiers. The two components must be combined by a frequency selective network based on a capacitor and inductor. The inductor of this network is usually very large in value, therefore taking up a large board space as well as being expensive. This frequency selective network will also introduce distortion at the crossover frequency which is not desirable.

FIG. 2 shows a known alternative configuration where the envelope modulator is of a single band type and uses a class G amplifier configuration. In contrast to the split-frequency envelope modulators shown in FIG. 1 the entire bandwidth of the envelope signal is applied to the input of the class G amplifier in this configuration. The class G amplifier has a bandwidth that is sufficient to amplify the entire bandwidth of the envelope signal so that the output signal provided by the amplifier provides a low frequency or DC output as well as high frequency AC output, both reflecting the low frequency/DC and the AC components of the input envelope signal. The voltage output by the class G amplifier of the envelope modulator in FIG. 2 is directly applied to the RF amplifier.

Though this amplifier configuration in FIG. 2 does not result in a null value in the frequency domain, this has a lower efficiency when compared to split-frequency architecture since it amplifies the entire bandwidth of the signal.

A charge pump as shown in FIG. 3 is capable of producing an output voltage which is double its input. In such an arrangement a switch is used to alternatively charge one capacitor from the supply voltage and then switch it in series with the supply voltage. When connected in series with the supply voltage, charge is passed to the output capacitor which maintains twice the supply voltage. A number of charge pumps can be cascaded to achieve higher output voltages. However the charge pumps are not generally dynamically controllable and the output voltage is always a multiple of the input.

The described embodiments overcome the drawbacks of existing amplifier configuration by cascading amplifiers with floating power supplies in a circuit to reproduce signals with high peak-to-average power ratio (PAPR) for envelope modulation applications. The embodiments are suitable for use with amplifiers intended for high PAPR modulation scheme like OFDM, for example the LTE or DVB standards, using envelope tracking and modulation. Embodiments extend to amplifiers for use in such high PAPR modulation schemes that comprises cascaded amplifiers and power supplies.

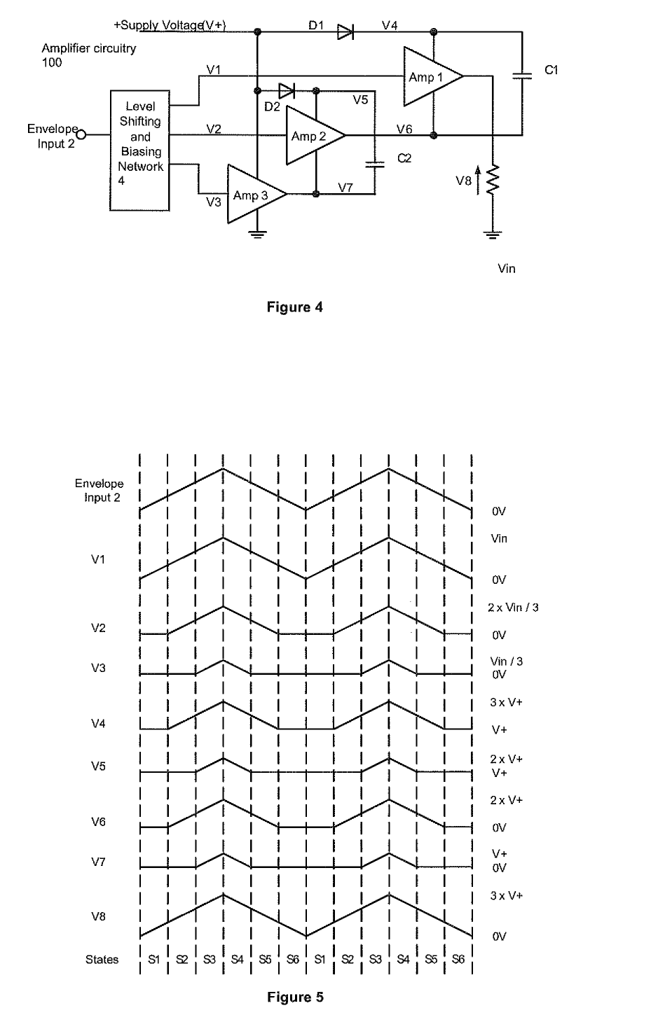

An amplifier circuitry 100 according to an embodiment is shown in FIG. 4. The circuitry 100 comprises a stacked amplifier structure, i.e. incorporating cascaded amplifiers for use in an envelope modulator. This figure shows a stacked amplifier configuration driving a resistive load which represents an RF Power Amplifier (RF PA) with a voltage V8 produced across the load. Three amplifiers Amp 1, Amp 2 and Amp 3 are shown in a stacked configuration such that the output of one amplifier drives the power supply for the next amplifier, such as shown in FIG. 4.

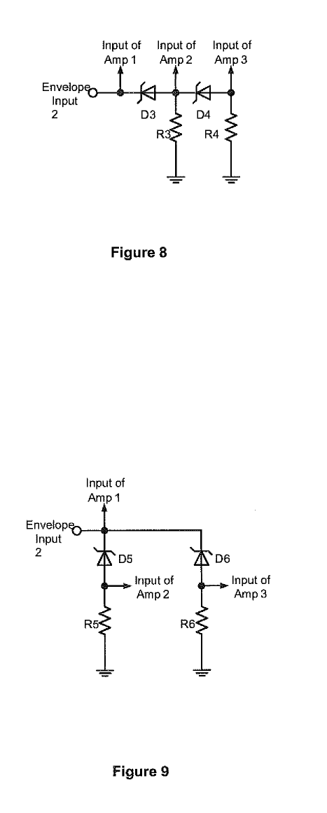

An envelope input 2 is provided to a level shifting and biasing network 4. This envelope input represents a signal provided from an envelope detector or baseband processing (not shown in FIG. 4) that is indicative of an instantaneous magnitude of the envelope of an RF signal (not shown in FIG. 4) that is to be amplified by the amplifier circuitry 100. The biasing network 4 includes a circuit that produces biased voltages for driving amplifiers Amp 1-3 based on the voltage range of the input envelope signal 2. The biasing network 4 is configured to receive the envelope of a signal and provide an input signal for each amplifier based on the voltage of the envelope input. In the described embodiments, the input signal voltage for each amplifier Amp 1-3 are different from the other amplifiers such that V1<V2<V3 where V1, V2 . . . VN are the input voltages for each of the Amp 1-3, respectively. The biasing network preferably comprises a zener diode configuration and is configured to provide an input signal to an amplifier if the voltage of the envelope input exceeds the breakdown voltage of a zener diode controlling the input for that particular amplifier. Therefore, an input will be provided to Amp 2 in amplifier circuitry 100 only if the voltage of the envelope input is at V2 or more. Similarly, an input will be provided to Amp 2 only if the envelope input is at V3 or more. Possible implementation of this level shifting and biasing network 4 that can be used in the embodiments is shown in FIGS. 8 and 9 described later herein.

A voltage will always be present at V1 for driving Amp 1 for amplifying the envelope signal. If the envelope input 2 is in the lower third of its, a voltage will appear at just V1. A voltage only appears at V2 for driving Amp 2 when the envelope input 2 is in the middle third of its range. A voltage appears at V3 for driving Amp 3 only when the envelope input 2 is in the upper third of its range.

A positive supply voltage V+ is provided to charge storage devices C1 and C2, which are coupled the amplifiers in amplifier circuitry 100. C1 and C2 are preferably capacitors that act as floating power supplies for Amp 1 and 2, respectively. The output V7 from Amp 3 is coupled to C2 which can supply power to Amp 2. Similarly, the output V6 from Amp 2 is coupled to C1 which can supply power to Amp 1. Current from V+ to drive an output load, represented by the resistive load (RF PA), passes through each of the amplifiers (Amp 1, Amp 2 and Amp 3) at all times in the described embodiments.

At low input signal levels where an envelope input 2 is in the lower third of its range, driver voltages V2 and V3 for Amp 2 and Amp 3, respectively are at ground. The outputs of Amp 2 and Amp 3 are therefore at their lower extremity, so that output voltages V6 and V7 are effectively at ground. In this state where a voltage only appears at V1, only Amp 1 operates as an amplifier in the amplifier circuitry 100. Current flows through diodes D1 and D2 to charge capacitors C1 and C2 to the supply voltage (V+). This is represented by state S1 in FIG. 5.

As the envelope input 2 enters the middle third of its voltage range, a voltage appears at V2 for driving Amp 2 thereby causing the output voltage at V6 to rise. Because of the charge built up in C1 that is cascaded with Amp 1, V4 will also rise by a similar amount and feed this increase in power to a voltage supply input for Amp 1. Without V4 rising, the output voltage V8 would be limited to supply voltage V+. This is represented by state S2 in FIG. 5.

If the envelope input voltage 2 continues to increase, a voltage will appear at V3 for driving Amp 3. This will cause an output voltage at V7 and hence raise output voltage

V5 above the supply voltage V+. This increase in V5 will feed into a voltage supply input for Amp 2. The output of the amplifier circuitry V8 is obtained from Amp 1. V8 represents the amplified envelope that can be provided to a voltage supply input of an RF power amplifier. Under such operation, the output load V8 can achieve peak amplitude of three times of the supply voltage V+.

Although the amplifier circuitry 100 is shown to include three amplifiers (Amp 1-3), it would be understood by a skilled person that a similar operation could be obtained by the amplifier circuitry 100 if it consisted of only two amplifiers, or as many more as are practically feasible. Charge storage devices that act as floating power supplies can be cascaded with the amplifiers in the manner described above, such that the output voltage of one amplifier is used to drive the power supply to the next in order to achieve higher output voltages. For instance, an amplifier circuitry without Amp 3 and charge storage device (C2, D2) of FIG. 4 would provide an output load V8 with peak amplitude of 2 times V+. Similarly, an amplifier circuitry with an additional amplifier and charge storage device that acts as a floating power supply for Amp 3 and feeds into a voltage supply input of Amp 3 provides an output load V8 with a peak amplitude of 4 times the supply voltage V+.

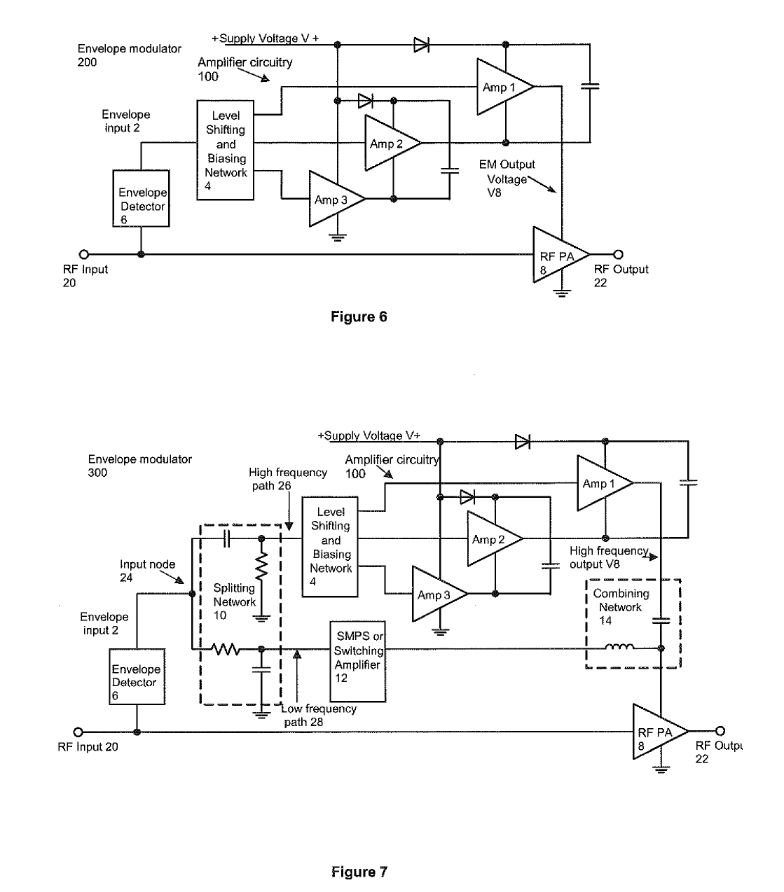

FIG. 6 shows an Envelope Modulator 200 according to an embodiment, the envelope modulator 200 incorporating the amplifier circuitry 100 of FIG. 4. Some of the components therefore correspond to the components of the amplifier circuitry 100 of FIG. 4 and are identified by like reference numerals. The envelope modulator 200 comprises an RF input 20 to which an RF signal that is to be amplified by an RF Power amplifier RF PA 8 is applied. The envelope modulator 200 also comprises an RF output 22 to which a load can be connected (such as V8 shown in FIG. 4 that feeds into the voltage supply input of RF PA 8). An envelope detector 6 is connected to the RF input 20. This envelope detector provides a signal indicative of an instantaneous magnitude of the envelope of the RF signal 20 to a biasing network 4. This biasing network provides the biased driving voltages for the amplifiers Amp 1-3.

The operation of the amplifier configuration of the envelope modulator 200 is similar to the operation of the amplifier circuitry 100 explained above in relation to FIG. 4. The envelope modulated output voltage, which is represented by the resistive load V8 in FIG. 4, can achieve peak amplitude of three times of a supply voltage V+ for driving the RF PA 8 in the envelope modulator 200.

In the embodiment of FIG. 6, the full envelope signal is supplied by the amplifiers Amp 1-3 of amplifier circuitry 100. Therefore, there is no frequency splitting of the architecture such as shown in the envelope modulator of FIG. 1. This configuration eliminates a null reading in the envelope signal's frequency domain at the crossover frequency. Furthermore, a combining network such as shown in the known envelope modulator FIG. 1 is not necessary in envelope modulator 200 of FIG. 6. Therefore large inductors that are usually required by such combining networks are not required. Therefore, envelope modulator 200 according to this embodiment achieves a higher efficiency than existing arrangements such as shown in FIGS. 1 and 2 and also results in a low-cost and physically compact envelope modulator since large and expensive components splitting/combining networks are not needed.

It will be appreciated that the amplifier circuitry 100 of FIG. 4 can also be incorporated in existing split-frequency envelope modulators such as shown in FIG. 1. Such an arrangement is useful in situations when it is preferred to use a split-frequency modulator. For instance, such envelope modulators may have already been chosen for their efficiency and it is desirable to increase the efficiency of the split-frequency modulator using the existing envelope modulator components. Incorporating amplifier circuit 100 increases the efficiency of such modulators, despite the drawbacks of split-frequency envelope modulator explained above in relation to FIG. 1. An embodiment incorporating the amplifier circuitry 100 into a split frequency envelope modulator is shown in FIG. 7. As can be seen from this figure, in contrast to the envelope modulator of FIG. 1, the linear amplifier of FIG. 1 is replaced with the amplifier circuitry 100. Here, the envelope input 2 from the envelope detector 6 is provided to an input node 24. The envelope modulator 300 in this embodiment comprises two signal paths, one high frequency signal path 26 and a low frequency signal path 28. Both these share the common input node 24. The high frequency component 26 of envelope modulator 300 is amplified by the amplifier circuitry 100 and a capacitor is used to feed the amplified signal V8 to the voltage supply input of the RF amplifier 22. The high frequency output signal V8 achieves peak amplitude of three times supply voltage V+.

The low frequency signal path 28 of the envelope modulator 300 of this embodiment uses a switched mode power supply (SMPS) 12 to amplify the low frequency components 28 of the envelope signal 2. The amplified signal provided by the SMPS 12 is fed to the voltage supply input of the RF amplifier 8 via an inductor. This inductor forms a combining network 14 together with the capacitor provided at the output of the high frequency current path 26. This combining network 14 may comprise high and low pass filters in the high and low frequency paths, respectively.

The use of the amplifier circuitry 100 greatly improves the efficiency of the envelope modulator 300, when compared to existing split—frequency envelope modulators that use class AB amplifiers for amplifying a high frequency envelope signal component, such as shown in FIG. 1. In a system where an OFDM modulated signal like LTE or DVB is used, the majority of the envelope signal power is contained in the low frequency (DC), typically 80%. Since an SMPS have an efficiency of 95%, the majority of the envelope signal is efficiently amplified. The remaining 20% is less efficiently amplified, but the configuration with amplifier circuitry 100 as shown in FIG. 7 is preferable over a class G or H class amplifier configuration where all of the envelope signal power is amplified by a low efficiency amplifier.

FIGS. 8 and 9 show two possible configurations for the biasing networks 4 in amplifier circuitry 100 to achieve the operation described in FIG. 5. FIG. 8 is a series configuration in which diodes D3 and D4 are zener diodes with an equal break down voltage and the envelope has amplitude of three times this breakdown voltage. The resistors R3 and R4 ensure that when the envelope signal's amplitude is small the outputs are held at a ground potential. FIG. 9 is a parallel configuration where zener diode D6 has a breakdown voltage twice that of zener diode D5, so the envelope amplitude needs to be greater for a signal to be applied to Amp 3. Again resistors R5 and R6 hold the outputs at ground potential. Biasing is not limited to the circuits shown in FIGS. 8 and 9. Biasing for the present embodiments could be achieved digitally, such as with three separate analogue signals driving amplifiers Amp 1 to Amp 3.

The amplifier circuitry 100 according to the embodiments as seen in FIG. 4 based on a stacked amplifiers configuration in which the output of one amplifier drives a power supply of the next is more efficient and compact when compared to the known envelope modulators of FIGS. 1 and 2. The described embodiments can reproduce high PAPR signal efficiently for envelope modulations applications, as shown in FIGS. 6 and 7.

Simulations predict that envelope modulators 200 and 300 shown in FIGS. 6 and 7 based on a three amplifier Amp 1-3 configuration achieves a theoretical maximum efficiency of 67% for an 8.5 dB peak-to-average power ratio (PAPR) LTE envelope signal. With four such amplifiers, this efficiency increases to 72.4%.

The described embodiments are preferably intended for small base stations and transmitters/terminals such as low power amplifiers for both terminals and femtocell base stations, rather than large (>1 kW) type of transmitters. The base stations may be operated according to an OFDM standard, such as the LTE or WiMAX standards. The transmitter may be operating according to the DVB standard. The described embodiments may also be used for high power applications and larger transmitters. In this case, provisions for suitable power handling for the amplifiers of the amplifier circuitry must be made.

While certain embodiments have been described, these embodiments have been presented by way of example only, and are not intended to limit the scope of the inventions. Indeed, the novel devices, methods, and products described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope of the embodiments.

1. Amplifier circuitry for an envelope modulator comprising:
a plurality of amplifiers for driving a load, each amplifier receiving an input representing an envelope of a signal to be amplified; one or more charge storage devices coupled to one or more of said plurality of amplifiers, said plurality of amplifiers and charge storage device(s) arranged to receive a supply voltage V+, the charge storage devices being charged to said supply voltage V+; wherein the plurality of amplifiers are arranged so that the output of a second one of said plurality of amplifiers is connected to one of the charge storage devices, said charge storage device being connected to a first one of said amplifiers for supplying a charge to the first amplifier, whereby an increase in the output voltage of the second amplifier causes the charge supplied to the first amplifier to increase above the supply voltage V+ such that the output voltage of the load driven by the amplifier circuitry is increased above the supply voltage V+.

2. The amplifier circuitry as claimed in claim 1 including a biasing network for receiving an envelope of a signal to be amplified and providing an input signal for each amplifier based on the voltage of the envelope input, the input signal voltage for each amplifier being different to the other amplifiers such that V1<V2< . . . VN, where N being the number of amplifiers in the amplifier circuitry and V1, V2 . . . VN being the input voltages for each of the amplifiers 1 . . . N, respectively.

3. The amplifier circuitry as claimed in claim 2 wherein the biasing network comprises a zener diode configuration arranged to provide an input signal to an amplifier of the amplifier circuitry when the voltage of the envelope input exceeds the breakdown voltage of a zener diode controlling the input for said amplifier.

4. The amplifier circuitry as claimed in any of the proceeding claims wherein an input signal V2, V2>V1, provided to the second amplifier causes an increase in the output voltage V6 of the second amplifier such that the voltage V4 supplied to the first amplifier via the charge storage device is also increased by the same amount above the supply voltage V+.

5. The amplifier circuitry as claimed in clam 4 further including a third amplifier and a further charge storage device arranged such the output of the third amplifier is connected to the further charge storage device, said further charge storage device connected to the second amplifier for supplying a charge to the second amplifier, wherein an input signal V3, V3>V2>V1, provided to the third amplifier causes an increase in the output voltage V7 of the third amplifier such that the voltage V5 supplied to the second amplifier via the further charge storage device is increased by the same amount above the supply voltage V+.

6. The amplifier circuitry as claimed in any preceding claim wherein each of the charge storage devices is a capacitor, and wherein a supply voltage flows through a diode to charge the capacitor to the supply voltage V+.

7. The amplifier circuitry as claimed in any one of claims 1 to 6 wherein said charge storage devices are floating power supplies for supplying a voltage to one of said plurality of amplifiers and feeds into the voltage supply input of said amplifier such that the output voltage of that amplifier is increased based on the charge in said charge storage device.

8. An envelope modulator comprising the amplifier circuitry as claimed in any one of the preceding claims, the envelope modulator further including:
an RF input for receiving an RF signal that is to be amplified;
an envelope detector for providing an envelope input signal indicative of an instantaneous magnitude of the envelope of said RF signal to said amplifier circuitry; and
an RF power amplifier for providing an amplified RF output signal;
wherein, the amplifier circuitry is configured to feed an amplified envelope signal output to a voltage supply input of the RF power amplifier.

9. An envelope modulator comprising the amplifier circuitry as claimed in any one of claims 1 to 7, the envelope modulator being a split-frequency envelope modulator further including:
an RF input for receiving an RF signal that is to be amplified;
an envelope detector for providing an envelope signal indicative of an instantaneous magnitude of the envelope of said RF signal;
a splitting network for receiving the envelope signal from the envelope detector and splitting said envelope signal into a high frequency component and a low frequency component, the splitting network being arranged to provide the high frequency component of the envelope signal to the amplifier circuitry, and to provide the low frequency component of the envelope signal to a further amplifier;
a combining network for combining the outputs of the amplifier circuitry and further amplifier provide an amplified envelope signal; and
an RF power amplifier for providing an amplified RF output signal
wherein, the amplifier circuitry is configured to feed an amplified envelope signal output to a voltage supply input of the RF power amplifier.

10. An RF amplifier comprising an envelope modulator according to any one of claim 8 or 9.

11. A base station or a transmitter comprising an RF amplifier according to claim 10.

12. A method for amplifying a signal using the amplifier circuitry of any one of claims 1 to 7 comprising the steps of:
providing an input signal representing an envelope of a signal to be amplified to a plurality of amplifiers, said plurality of amplifiers provided for driving a load;
providing one or more charge storage devices coupled to one or more of said plurality of amplifiers;
providing a supply voltage V+ to said plurality of amplifiers and charge storage devices, the charge storage devices being charged to said supply voltage V+; and
connecting the output of a second one of said plurality of to one of the charge storage devices, said charge storage device being connected to a first one of said amplifiers for supplying a charge to the first amplifier, whereby an increase in the output voltage of the second amplifier causes the charge supplied to the first amplifier to increase above the supply voltage V+ such that the output voltage of the load driven by the amplifier circuitry is increased above the supply voltage V+.

13. An envelope modulation method implemented by the envelope modulator of claim 8 comprising the steps of:
providing an RF input for receiving an RF signal that is to be amplified;
providing an envelope input signal by an envelope detector to the amplifier circuitry of the envelope modulator, said signal indicative of an instantaneous magnitude of the envelope of said RF signal;
amplifying the envelope signal in the amplifier circuitry having a plurality of amplifiers and one or more charge storage devices, and providing an amplified output; and
providing the amplified output to a voltage supply input of an RF power amplifier for amplifying the RF signal.

14. An envelope modulation method implemented by the envelope modulator of claim 9 comprising the steps of:
providing an RF input for receiving an RF signal that is to be amplified;
providing an envelope input signal by an envelope detector, said signal indicative of an instantaneous magnitude of the envelope of said RF signal
receiving said envelope signal and splitting the signal into a high frequency component and a low frequency component by a splitting network;
providing the high frequency component of the envelope signal to the amplifier circuitry of the envelope modulator;
providing the low frequency component of the envelope signal to a further amplifier;
combining the outputs of the amplifier circuitry and further amplifier in a combining network to provide an amplified envelope signal; and
providing the amplified output to a voltage supply input of an RF power amplifier for amplifying the RE signal.
